(19) United States
(12) Patent Application Publication
(10) Pub. No.: US 2021/0111304 A1
(43) Pub. Date: Apr. 15, 2021

(54) SURFACE MODIFICATION METHOD OF ALUMINUM NITRIDE CERAMIC SUBSTRATE

(71) Applicant: National Chung-Shan Institute of Sceince and Technology, Taoyuan City (TW)

(72) Inventors: Chun-Te Wu, Taoyuan City (TW); Yang-Kuo Kuo, Taoyuan City (TW); Hong-Ting Huang, Taoyuan City (TW)

(21) Appl. No.: 17/068,811

(22) Filed: Oct. 12, 2020

(30) Foreign Application Priority Data
Oct. 15, 2019 (TW) 108137418

(51) Int. Cl. H01L 33/00; C23C 16/30; C23C 16/18; C23C 14/18; C23C 14/06

(52) U.S. Cl. CPC H01L 33/0095; H01L 33/0075; C23C 16/303; H01L 2933/0025; C23C 14/18; C23C 14/0617; C23C 16/18

(57) ABSTRACT

A surface modification method of an aluminum nitride ceramic substrate uses a sputtering deposition and a metal organic chemical vapor deposition (MOCVD) to perform a surface modification of the polycrystalline aluminum nitride ceramic substrate. Accordingly, an aluminum nitride layer is epitaxially grown in two stages of temperature by MOCVD, such that a crystallization phase of monocrystalline aluminum nitride material may be formed on the surface of the polycrystalline aluminum nitride ceramic substrate, so as to decrease a surface roughness of the polycrystalline aluminum nitride ceramic substrate.

### BACKGROUND OF THE INVENTION

### 1. Field of the Invention

The present invention relates to a surface modification method of an aluminum nitride ceramic substrate, and more particularly to a surface modification method of a polycrystalline aluminum nitride ceramic substrate.

### 2. Description of the Prior Art

Since electronic components require and trend towards smaller size, improved performance, and environmental protection and energy saving, high-density and high-energy electronic components such as LED street lights, MOSFET, IGBT and laser components, that are high-power, high-frequency or high-heat environments and have more than 100 W/cm² of heat dissipation, have become the key technological projects for the major development of related industries. If the heat generated by the long-term work of these densely arranged components is not timely removed from the limited heat dissipation space of the package, the performance and lifetime of these components will be reduced due to the increase of the junction temperature. Also, the accumulation of high-temperature thermal stress between materials will inevitably cause component reliability problems. Therefore, it needs to eliminate the heat with an excellent heat dissipation package and high thermal conductivity materials.

In the existing technology, a ceramic substrate is mostly used for such as light-emitting diodes, stacked memories and stacked integrated circuits use silicon (Si) materials and alumina (Al₂O₃) ceramic materials to serve as a heat dissipation substrate. Recently, aluminum nitride is very popular among the electronic applied materials because of its high thermal conductivity (170-230 W/mK, close to silicon carbide and beryllium oxide, and 5-7 times the thermal conductivity of aluminum oxide), low dielectric constant, low dielectric loss, good electrical insulation, low thermal expansion coefficient close to silicon (4.2×10⁻⁶/° C.) and gallium arsenide (5.7×10⁻⁶/° C.), no toxicity of beryllium oxide and lower producing cost. Thus, aluminum nitride may be used in a wide range of applications, such as packaging substrates of semiconductor and microelectronics, carrier substrates of high-brightness LED chips, automotive electronics, lighting components, heat dissipation materials of high-power electronic components, etc. Aluminum nitride has great potential to gradually replace other ceramic substrate materials in the future.

It is known that the heat conduction coefficient of the commercially available monocrystalline aluminum nitride ceramic substrate is about 200-240 W/mK, and the heat conduction coefficient of the polycrystalline aluminum nitride ceramic substrate is about 170-180 W/mK. Presently, the commercially available product is the polycrystalline aluminum nitride ceramic substrate mainly, and its price is much lower than the price of the monocrystalline aluminum nitride ceramic substrate. However, the types of the crystallization phase of the polycrystalline aluminum nitride ceramic substrate are more than the monocrystalline aluminum nitride ceramic substrate, and the surface of the polycrystalline aluminum nitride ceramic substrate is not conducive to make subsequent process(es) be performed on the components such as light-emitting diodes, stacked memories and stacked integrated circuits.

In addition, the polycrystalline aluminum nitride ceramic substrate is made of aluminum nitride powder, wherein the aluminum nitride powder may be processed through such as hydraulic forming, cold isostatic pressing (CIP) densification, degumming, high temperature sintering, etc., and then, the precision cutting process and grinding and polishing process are performed to obtain the polycrystalline aluminum nitride ceramic substrate with a flatten surface. However, when performing the grinding and polishing process, this process will cause the polycrystalline aluminum nitride powder to peel off, such that some holes may appear on the polycrystalline aluminum nitride ceramic substrate, so as to increase the surface roughness of the polycrystalline aluminum nitride ceramic substrate.

The most attractive application of aluminum nitride substrate is the development of ultraviolet (UV) LED, wherein UV LED has great commercial value in biomedical diagnosis. Presently, the most commonly used substrate for UV LED is sapphire, but a lattice difference between sapphire and aluminum nitride is up to 13%. Therefore, it is a big challenge to grow monocrystalline aluminum nitride or aluminum gallium nitride (AlGaN) with high aluminum content on the sapphire substrate. Also, this is one of the reasons why the luminous efficiency of the UV LED drops sharply once the wavelength of the UV LED is below 300 nm. Although some research teams have proposed a solution to replace the sapphire substrate with a monocrystalline aluminum nitride substrate, due to the high price of the monocrystalline aluminum nitride substrate, it cannot replace the sapphire substrate in the short term. If we can use MOCVD to grow a monocrystalline aluminum nitride thin film with desired quality on the polycrystalline aluminum nitride substrate, this will be an exciting research direction in the development of UV LED.

As the result, in order to solve the above problems, we need to develop a low cost, low surface roughness and monocrystalline aluminum nitride ceramic substrate, so as to make the subsequent process be performed on components such as light-emitting diodes, stacked memories and stacked integrated circuits.

### SUMMARY OF THE INVENTION

Regarding the aforementioned disadvantages of the prior art, the present invention uses a sputtering deposition and a metal organic chemical vapor deposition (MOCVD) to perform a surface modification of the aluminum nitride ceramic substrate. A titanium metal layer serving as an adhesive layer is formed on an aluminum nitride substrate by a sputtering deposition. Then, an aluminum nitride thin film is formed by another sputtering deposition to serve as a buffer layer between an epitaxial layer and the substrate. Next, an aluminum nitride layer is epitaxially grown in two stages of temperature by MOCVD, wherein lateral growth of crystal nuclei is accelerated by increasing the substrate temperature, such that the independent crystal nuclei are connected to each other to form a single epitaxial layer.

In order to achieve the above purposes, the present invention proposes a surface modification method of an aluminum nitride ceramic substrate. Steps of the surface modification method of the aluminum nitride ceramic substrate include: (A) providing a polycrystalline aluminum nitride substrate, and forming a titanium metal layer on the polycrystalline aluminum nitride substrate by a sputtering deposition; (B) forming an aluminum nitride buffer layer on the titanium metal layer by another sputtering deposition; (C) forming an aluminum nitride thin film epitaxial layer on the aluminum nitride buffer layer by a metal organic chemical vapor deposition (MOCVD), wherein a thickness of the aluminum nitride thin film epitaxial layer is less than 1 μm; and (D) continuing the metal organic chemical vapor deposition and increasing a process temperature of the metal organic chemical vapor deposition to form an aluminum nitride thick film epitaxial layer on the aluminum nitride thin film epitaxial layer, wherein a thickness of the aluminum nitride thick film epitaxial layer is greater than 1 μm.

In the above, a thickness of the titanium metal layer in the step (A) may range from 100 nm to 500 nm.

In the above, the sputtering deposition in the step (A) may be performed with a titanium target, and a sputtering gas of the sputtering deposition in the step (A) may be argon.

In the above, a thickness of the aluminum nitride buffer layer in the step (B) may range from 100 nm to 500 nm.

In the above, the sputtering deposition in the step (B) may be performed with an aluminum target, and a sputtering gas of the sputtering deposition in the step (B) may be a combination of argon and nitrogen.

In the above, in the step (C), reactants may be trimethyl aluminum (Al₂(CH₃)₆) and ammonia (NH₃), and an epitaxial growth temperature may range from 950° C. to 1030° C.

In the above, in the step (D), reactants may be trimethyl aluminum (Al₂(CH₃)₆) and ammonia (NH₃), and an epitaxial growth temperature may range from 1030° C. to 1160° C.

In the above, crystallization phases of the aluminum nitride buffer layer may include: a (002) crystallization phase of which a diffraction angle 2θ is between 35.5° and 36.5°, a (102) crystallization phase of which a diffraction angle 2θ is between 49.5° and 50.5°, and a (103) crystallization phase of which a diffraction angle 2θ is between 65.5° and 66.5°.

In the above, the thickness of the aluminum nitride thin film epitaxial layer may range from 100 nm to 500 nm, the thickness of the aluminum nitride thick film epitaxial layer may range from 1 μm to 5 μm. The aluminum nitride thin film epitaxial layer and the aluminum nitride thick film epitaxial layer may further have a monocrystalline aluminum nitride with a crystal face which is (101).

The present invention may make the crystallization phase of the monocrystalline aluminum nitride material be formed on the surface of the polycrystalline aluminum nitride ceramic substrate, such that a surface roughness of the polycrystalline aluminum nitride ceramic substrate may be decreased, and epi facets are distributed uniformly and are pyramids, wherein the side of the pyramid is 62° to the c-plane (i.e., the surface parallel to the substrate surface), which is a crystal face of (101). The crystal face of (101) is very helpful to the luminous efficiency of UV LED, wherein it may greatly reduce the probability of total reflection of the light beam inside the component, so as to effectively improve the light extraction efficiency of the LED.

The above and the following detailed description and drawings are intended to further illustrate the manner, means, and effect of the present invention for achieving predetermined purposes. Other purposes and advantages of the present invention are described in the following detailed description and drawings.

### BRIEF DESCRIPTION OF THE DRAWINGS

FIG. 1 is a flowchart of a surface modification method of an aluminum nitride ceramic substrate according to the present invention.

FIG. 2 is a schematic diagram showing a cross-sectional view of a polycrystalline aluminum nitride ceramic substrate after processing surface modification according to an embodiment of the present invention.

FIG. 3 shows X-ray diffraction spectrums of a polycrystalline aluminum nitride ceramic substrate after processing a surface modification according to an embodiment of the present invention.

FIG. 4 shows SEM pictures of a surface and a cross-sectional view of an epitaxial layer of a polycrystalline aluminum nitride ceramic substrate after processing a surface modification according to an embodiment of the present invention.

FIG. 5 shows AFM pictures of a polycrystalline aluminum nitride ceramic substrate and a polycrystalline aluminum nitride ceramic substrate after processing a surface modification according to an embodiment of the present invention.

### DETAILED DESCRIPTION

Specific examples will be detailed in the follow description to explain an implementation of the present invention. Those skilled in the art can easily understand an advantage and an effect of the present invention from contents disclosed in this specification.

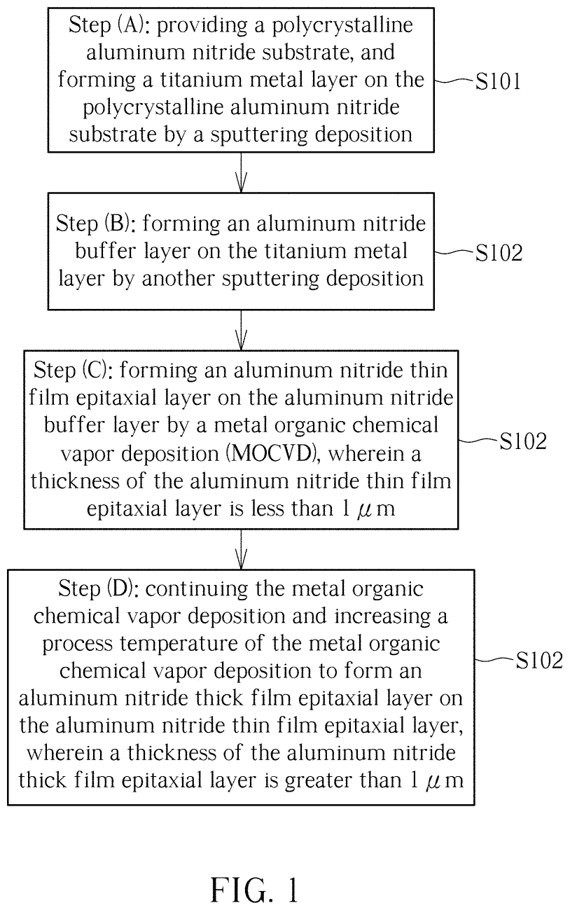

Referring to FIG. 1, FIG. 1 is a flowchart of a surface modification method of an aluminum nitride ceramic substrate according to the present invention. As shown in FIG. 1, steps of the surface modification method of the aluminum nitride ceramic substrate of the present invention include: (A) providing a polycrystalline aluminum nitride substrate, and forming a titanium metal layer on the polycrystalline aluminum nitride substrate by a sputtering deposition (step S101); (B) forming an aluminum nitride buffer layer on the titanium metal layer by another sputtering deposition (step S102); (C) forming an aluminum nitride thin film epitaxial layer on the aluminum nitride buffer layer by a metal organic chemical vapor deposition (MOCVD), wherein a thickness of the aluminum nitride thin film epitaxial layer is less than 1 μm (step S103); and (D) continuing the metal organic chemical vapor deposition and increasing a process temperature of the metal organic chemical vapor deposition to form an aluminum nitride thick film epitaxial layer on the aluminum nitride thin film epitaxial layer, wherein a thickness of the aluminum nitride thick film epitaxial layer is greater than 1 μm (step S104).

### Embodiment

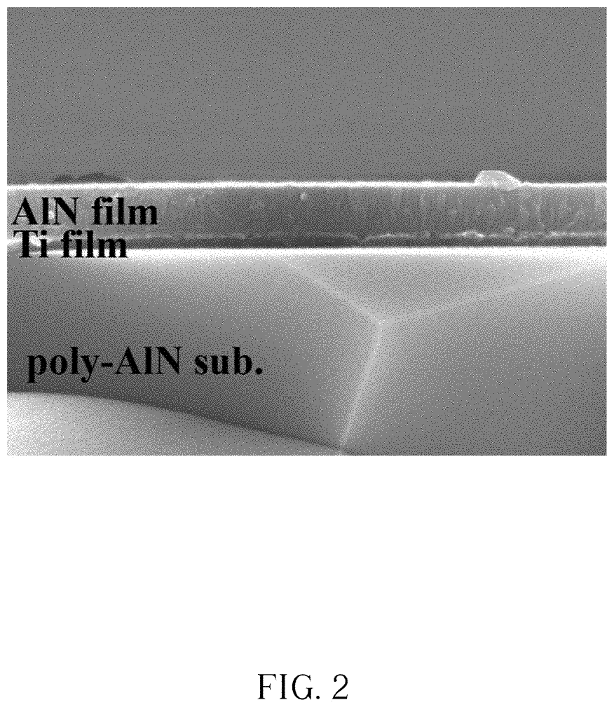

In this embodiment, the polycrystalline aluminum nitride substrate is provided first. A titanium metal layer is formed on the polycrystalline aluminum nitride substrate by a sputtering deposition (using a titanium target, and sputtering parameters: 100 W of power, 30-150 minutes of time, 8 sccm of flow rate of argon, and 5×10⁻³ torr of pressure) to serve as an adhesive layer. Then, an aluminum nitride thin film is formed by another sputtering deposition (using an aluminum target, and sputtering parameters: 100 W of power, 30-150 minutes of time, 8 sccm of flow rate of argon/nitrogen, and 5×10⁻³ torr of pressure) to serve as a buffer layer between an epitaxial layer and the substrate. Next, by using the metal organic chemical vapor deposition (MOCVD) and using trimethyl aluminum (TMAl) and ammonia (NH₃) to be raw materials, an aluminum nitride thin film epitaxial layer and an aluminum nitride thick film epitaxial layer are epitaxially grown in two stages (first stage MOCVD parameters: 950-1030° C. of temperature, 30 minutes of time, 10 sccm of flow rate of TMAl/500 sccm of flow rate of NH₃, and 200 mbar of pressure; second stage MOCVD parameters: 1030-1160° C. of temperature, 60 minute of time, 20 sccm of flow rate of TMAl/1000 sccm of flow rate of NH₃, and 200 mbar of pressure), so as to complete the surface modification of the polycrystalline aluminum nitride ceramic substrate of the present invention. Referring to FIG. 2, FIG. 2 is a schematic diagram showing a cross-sectional view of a polycrystalline aluminum nitride ceramic substrate after processing surface modification according to an embodiment of the present invention. As shown in FIG. 2, the structure includes a polycrystalline aluminum nitride ceramic substrate, a titanium metal thin film, an aluminum nitride thin film and an aluminum nitride epitaxial layer.

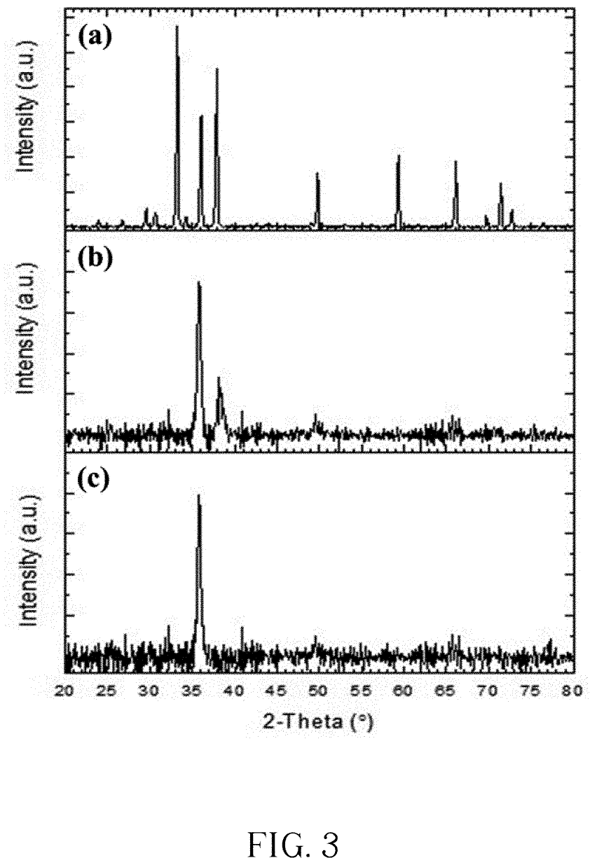

Referring to FIG. 3, FIG. 3 shows X-ray diffraction spectrums of a polycrystalline aluminum nitride ceramic substrate after processing a surface modification according to an embodiment of the present invention. The crystallization phase identification is performed by using X-ray diffractometer. First, the crystallization phase identification for the polycrystalline aluminum nitride ceramic substrate is performed. As shown in (a) of FIG. 3, it shows that the polycrystalline aluminum nitride ceramic substrate has diffraction peaks of the polycrystalline aluminum nitride material at 20=23.4°, 25.4°, 29.6°, 30.7°, 33.2°, 34.3°, 36.0°, 37.9°, 49.8°, 59.4°, 66.1°, 69.7°, 71.5° and 72.7°. One titanium metal thin film is formed on the polycrystalline aluminum nitride ceramic substrate by the sputtering deposition to serve as the adhesive layer, and then, the aluminum nitride buffer layer and the aluminum nitride epitaxial layer are formed on the titanium metal thin film/the polycrystalline aluminum nitride ceramic substrate by the sputtering deposition and the metal organic chemical vapor deposition (MOCVD). After that, as shown in (b) of FIG. 3, it shows that a diffraction peak of the titanium metal thin film appears at 2θ=38.2°. Finally, the crystallization phase identification for the surface of the aluminum nitride epitaxial layer/the aluminum nitride buffer layer/the titanium metal thin film (the adhesive layer)/the polycrystalline aluminum nitride ceramic substrate is performed by using the X-ray diffractometer with grazing incident diffraction. As shown in (c) of FIG. 3, single diffraction peak of the aluminum nitride thin film appears at 2θ=35.9°. It means that the surface of the polycrystalline aluminum nitride ceramic substrate may be indeed converted from polycrystalline phase to monocrystalline phase after the substrate surface modification technique is applied on the polycrystalline aluminum nitride ceramic substrate.

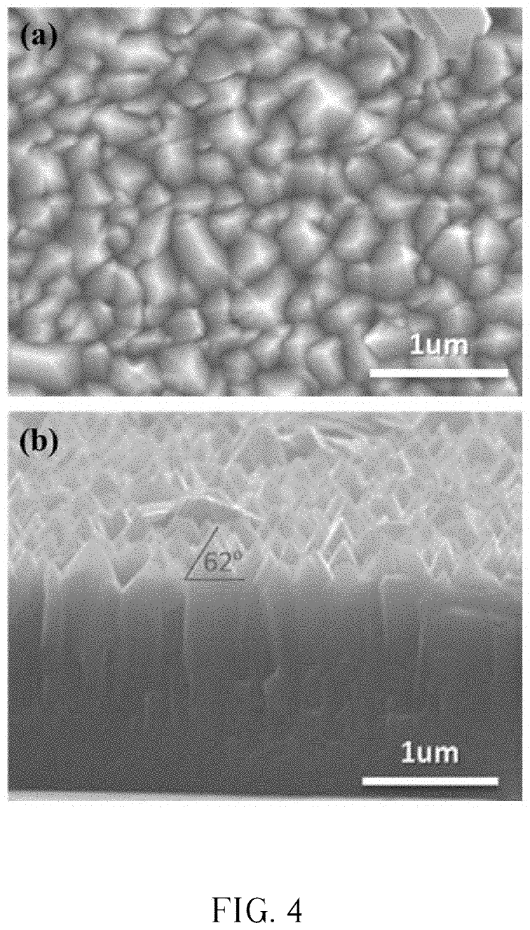

Referring to FIG. 4, FIG. 4 shows SEM pictures of a surface and a cross-sectional view of an epitaxial layer of a polycrystalline aluminum nitride ceramic substrate after processing a surface modification according to an embodiment of the present invention. The result shows that the aluminum nitride epitaxial layer prepared by the present invention has aluminum nitride crystal grains with more regular shape and uniform distribution of the epi facets, which are pyramids, wherein the side of the pyramid is 62° to the c-plane (i.e., the surface parallel to the substrate surface), which is a crystal face of (101). The distribution of the crystal face of AlN shown in SEM picture is consistent with the measuring result of XRD (X-ray diffraction). Generally, the quantum well grown on the c-plane is a polar quantum well which has the largest polarized electric field. The crystal face of (101) is very helpful to the luminous efficiency of UV LED, wherein the surface of this pyramid may greatly reduce the probability of total reflection of the light beam inside the component, so as to effectively improve the light extraction efficiency of the LED. The surface modification method proposed by the present invention may use a low cost to produce a larger and more uniform aluminum nitride substrate, which may serve as a high-quality GaN epitaxial substrate, thereby opening up the application market of UV LED.

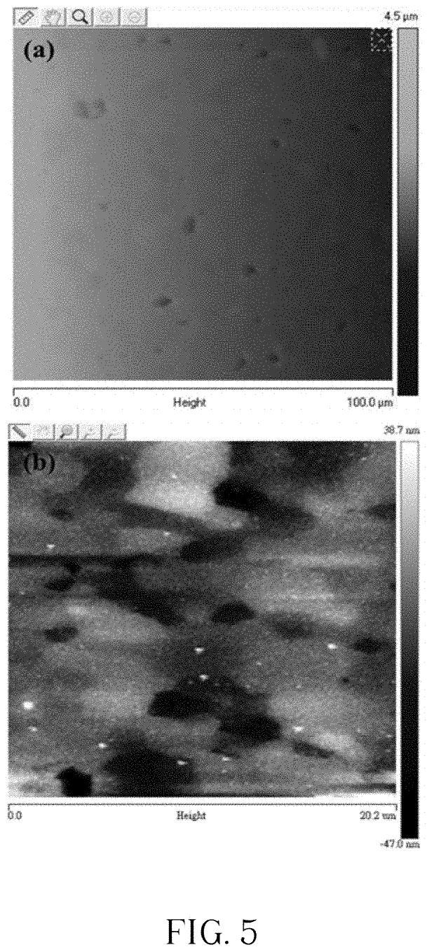

Referring to FIG. 5, FIG. 5 shows AFM pictures of a polycrystalline aluminum nitride ceramic substrate and a polycrystalline aluminum nitride ceramic substrate after processing a surface modification according to an embodiment of the present invention, wherein surface roughness measured by AFM is shown in table 1. Picture (a) of FIG. 5 is a surface picture of the polycrystalline aluminum nitride ceramic substrate of the present invention, and a combination of picture (a) and table 1 shows that a surface roughness of the polycrystalline aluminum nitride ceramic substrate is 25.5 nm; picture (b) of FIG. 5 is a surface picture of the polycrystalline aluminum nitride ceramic substrate after processing the surface modification according to the present invention, and a combination of picture (b) and table 1 shows that a surface roughness of the polycrystalline aluminum nitride ceramic substrate after processing surface modification according to the present invention is 7.8 nm. They show that the surface roughness of the polycrystalline aluminum nitride ceramic substrate may be effectively decreased from 25.5 nm to 7.8 nm when the surface modification method is applied on the polycrystalline aluminum nitride ceramic substrate.

TABLE 1

| | | Polycrystalline aluminum |
|---|---|---|
| | | nitride ceramic substrate |
| | Polycrystalline aluminum | after processing surface |
| | nitride substrate | modification |
| Surface roughness | 25.5 nm | 7.8 nm |
| (Ra) | | |

The surface modification method of the aluminum nitride ceramic substrate of the present invention uses the sputtering deposition and MOCVD to perform the surface modification of the aluminum nitride ceramic substrate. This surface modification method may make the crystallization phase of the monocrystalline aluminum nitride material be formed on the surface of the polycrystalline aluminum nitride ceramic substrate, such that the surface roughness of the polycrystalline aluminum nitride ceramic substrate may be decreased, and the epi facets are distributed uniformly and are pyramids. Thus, the polycrystalline aluminum nitride ceramic substrate may serve as a high-quality GaN epitaxial substrate, which is very helpful to the luminous efficiency of UV LED when it is applied to UV LED, wherein it may make the probability of total reflection of the light beam inside the component be greatly reduced to effectively improve the light extraction efficiency of the LED. The surface modification method of the aluminum nitride ceramic substrate according to the present invention may make the subsequent process be performed on components such as light-emitting diodes, stacked memories and stacked integrated circuits, so as to make these components be used in more fields in the future.

The above examples are merely to explain the features and effects of the present invention and not to limit the scope of the present invention. Those skilled in the art may make numerous modifications and alterations of the above embodiments without departing from the spirit and scope of the invention. Accordingly, the present invention should be construed as limited only by the metes and bounds of the appended claims.

What is claimed is:

1. A surface modification method of an aluminum nitride ceramic substrate, wherein steps of the surface modification method comprise:
(A) providing a polycrystalline aluminum nitride substrate, and forming a titanium metal layer on the polycrystalline aluminum nitride substrate by a sputtering deposition;
(B) forming an aluminum nitride buffer layer on the titanium metal layer by another sputtering deposition;
(C) forming an aluminum nitride thin film epitaxial layer on the aluminum nitride buffer layer by a metal organic chemical vapor deposition (MOCVD), wherein a thickness of the aluminum nitride thin film epitaxial layer is less than 1 μm; and
(D) continuing the metal organic chemical vapor deposition and increasing a process temperature of the metal organic chemical vapor deposition to form an aluminum nitride thick film epitaxial layer on the aluminum nitride thin film epitaxial layer, wherein a thickness of the aluminum nitride thick film epitaxial layer is greater than 1 μm.

2. The surface modification method of the aluminum nitride ceramic substrate of claim 1, wherein a thickness of the titanium metal layer in the step (A) ranges from 100 nm to 500 nm.

3. The surface modification method of the aluminum nitride ceramic substrate of claim 1, wherein the sputtering deposition in the step (A) is performed with a titanium target, and a sputtering gas of the sputtering deposition in the step (A) is argon.

4. The surface modification method of the aluminum nitride ceramic substrate of claim 1, wherein a thickness of the aluminum nitride buffer layer in the step (B) ranges from 100 nm to 500 nm.

5. The surface modification method of the aluminum nitride ceramic substrate of claim 1, wherein the sputtering deposition in the step (B) is performed with an aluminum target, and a sputtering gas of the sputtering deposition in the step (B) is a combination of argon and nitrogen.

6. The surface modification method of the aluminum nitride ceramic substrate of claim 1, wherein in the step (C), reactants are trimethyl aluminum (Al₂(CH₃)₆) and ammonia (NH₃), and an epitaxial growth temperature ranges from 950° C. to 1030° C.

7. The surface modification method of the aluminum nitride ceramic substrate of claim 1, wherein in the step (D), reactants are trimethyl aluminum (Al₂(CH₃)₆) and ammonia (NH₃), and an epitaxial growth temperature ranges from 1030° C. to 1160° C.

8. The surface modification method of the aluminum nitride ceramic substrate of claim 1, wherein the thickness of the aluminum nitride thin film epitaxial layer ranges from 100 nm to 500 nm.

9. The surface modification method of the aluminum nitride ceramic substrate of claim 1, wherein the thickness of the aluminum nitride thick film epitaxial layer ranges from 1 μm to 5 μm.

10. The surface modification method of the aluminum nitride ceramic substrate of claim 1, wherein the aluminum nitride thin film epitaxial layer and the aluminum nitride thick film epitaxial layer have a monocrystalline aluminum nitride with a crystal face which is (101).
